(19) United States
(12) Patent Application Publication
(10) Pub. No.: US 2025/0385074 A1
(43) Pub. Date: Dec. 18, 2025

(54) RADIO FREQUENCY MATCHING NETWORK

(71) Applicant: Applied Materials, Inc., Santa Clara, CA (US)

(72) Inventors: Edward P. HAMMOND, IV, Hillsborough, CA (US); David COUMOU, Santa Clara, CA (US)

(21) Appl. No.: 18/746,520

(22) Filed: Jun. 18, 2024

(51) Int. Cl. H01J 37/32

(52) U.S. Cl. CPC H01J 37/32183; H01J 37/32091; H01J 37/32449

(57) ABSTRACT

Certain aspects are directed towards an apparatus for semiconductor processing. The apparatus generally includes a plurality of chamber enclosures, each including a respective one of a plurality of matching networks and a respective one of a plurality of chamber loads and a splitting circuit having an input path coupled to a splitting node. Multiple split paths may be coupled between the splitting node and a respective one of the plurality of chamber enclosures through a respective one of multiple transmission lines, and each of the plurality of matching networks may be coupled between the respective one of the multiple transmission lines and the respective one of the plurality of chamber loads.

### BACKGROUND

### FIELD

Certain aspects of the present disclosure generally relate to a system and methods used in semiconductor device manufacturing. More specifically, certain aspects of the present disclosure relate to a plasma processing system used to process a substrate.

### DESCRIPTION OF THE RELATED ART

A plasma processing chamber may include a radio frequency (RF) signal generator, which supplies an RF signal to a power electrode. Plasma may be generated in the chamber using the RF signal generator. In some cases, an RF matching network (“RF match”) may be used to tune an RF waveform provided from the RF generator to deliver RF power to an apparent load, reducing reflected power and increasing power delivery efficiency. If the impedance of the load is not properly matched to the impedance of a source (e.g., the RF generator), a portion of the forward-delivered RF waveform can reflect in the opposite direction along the same transmission line. In some implementations, an RF signal generator may be used to provide power to multiple chamber loads.

### SUMMARY

Certain aspects are directed towards an apparatus for semiconductor processing. The apparatus generally includes a plurality of chamber enclosures, each including a respective one of a plurality of matching networks and a respective one of a plurality of chamber loads and a splitting circuit having an input path coupled to a splitting node. Multiple split paths are coupled between the splitting node and a respective one of the plurality of chamber enclosures through a respective one of multiple transmission lines, and each of the plurality of matching networks is coupled between the respective one of the multiple transmission lines and the respective one of the plurality of chamber loads.

Certain aspects are directed towards a method for semiconductor processing. The method generally includes generating, via a high-frequency signal generator, a high-frequency signal provided to a splitting node of a splitting circuit, and splitting, at the splitting node, the high-frequency signal to generate a plurality of split signals provided to a respective one of a plurality of chamber enclosures through a respective one of multiple transmission lines. Each of the plurality of chamber enclosures includes a respective one of a plurality of matching networks and a respective one of a plurality of chamber loads, and each of the plurality of matching networks is coupled between the respective one of the multiple transmission lines and the respective one of the plurality of chamber loads.

Certain aspects are directed towards a chamber enclosure. The chamber enclosure includes a chamber load, a high-frequency signal input port, a matching network having a first terminal coupled to the high-frequency signal input port and a second terminal coupled the chamber load, and a low-frequency high-frequency signal input port coupled to the second terminal of the matching network.

Certain aspects are directed towards a splitting circuit. The splitting circuit generally includes: an input path coupled to a splitting node; and multiple split paths coupled between the splitting node and a respective one of a plurality of chamber enclosures through a respective one of multiple transmission lines, wherein the input path includes a first impedance and each of the multiple split paths include a second impedance, the first impedance and the second impedance forming a matching network, wherein the second impedance is coupled the respective one of the transmission lines without another matching network.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates an isometric view of an exemplary cluster tool used to fabricate substrates, according to embodiments described herein.

FIGS. 2A and 2B illustrate semiconductor processing circuitry including splitting and pre-matching circuitry coupled to multiple RF enclosures having matching networks, in accordance with certain aspects of the present disclosure.

FIG. 3 is a flow diagram illustrating example operations for semiconductor processing, in accordance with certain aspects of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides an apparatus and method for processing substrates using a multi-chamber processing system (e.g., a cluster tool) adapted to process substrates. A cluster tool is a system comprising multiple chambers that perform various functions in the electronic device fabrication process. In some cases, a radio frequency (RF) generator (also referred to herein as a “high-frequency (HF) generator”) may be used to power the multiple chambers. For example, a splitting circuit may be used to split a current from an input path coupled to the RF generator to yield split currents for the multiple chambers. The splitting circuit may be coupled to chamber enclosures through respective transmission lines. In some aspects of the present disclosure, each chamber enclosure may be implemented with a matching network, allowing for the current across the transmission line to be reduced, which, in turn reduces power losses across the transmission line.

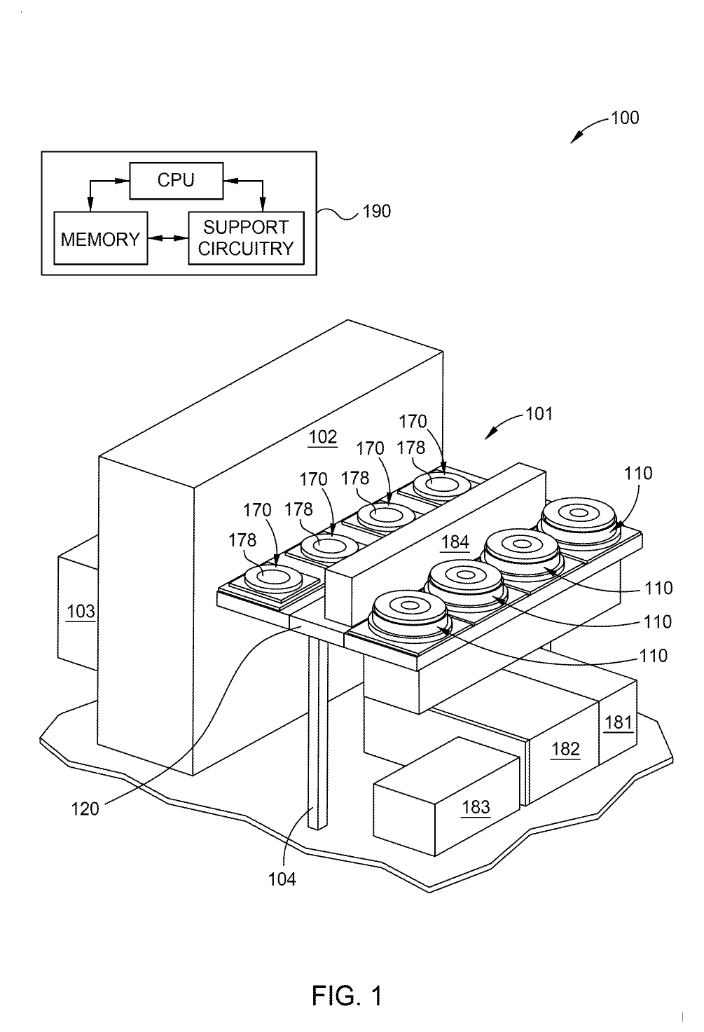

FIG. 1 is an isometric view of as aspect of a cluster tool 100 used to fabricate substrates. The cluster tool 100 includes a factory interface 102 and at least one processing mainframe 101.

The processing mainframe 101 includes, at least two substrate processing chambers 110, a substrate swapper assembly 120, at least two load locks 170, and a controller 190. While not intended to be limiting as to the scope of the disclosure provided herein, the disclosure provided herein primarily describes an aspect of the disclosure that includes a processing mainframe 101 that includes, at least four substrate processing chambers 110, a substrate swapper assembly 120, at least four load locks 170, and a controller 190. The load locks 170 and processing chambers 110 can be grouped in pairs, with each grouping having one load lock 170 opposing a corresponding processing chamber 110. The substrate swapper assembly 120 is located between the processing chambers 110 and the load locks 170. The substrate swapper assembly 120 includes a swapper for each pair of the processing chambers 110 and load locks 170, and each swapper is used to swap (e.g., move) substrates between the corresponding processing chamber 110 and load lock 170. The processing mainframe 101 may be supported in a position relative to the factory interface 102 by one or more supports 104, which may be a frame, used to support the weight of the processing mainframe 101.

As shown in FIG. 1, the processing mainframe 101 includes four processing chamber 110 and load lock 170 pairs. In some aspects, the processing mainframe 101 may have only one processing chamber 110 and load lock 170 pair. In some embodiments, the processing mainframe 101 may have two or three processing chamber 110 and load lock 170 pairs. In some aspects, the processing mainframe 101 may have more than four processing chamber 110 and load lock 170 pairs, as illustrated in FIG. 1. In some aspects, the processing mainframe 101 may have more than five processing chamber 110 and load lock 170 pairs or six processing chamber 110 and load lock 170 pairs.

The processing chambers 110 include a substrate support (e.g., pedestal, platen) and a processing kit and source assembly configured to process the substrate within the processing chamber 110. The processing chambers 110 may perform any number of processes such as preclean, chemical vapor deposition (CVD), plasma enhanced chemical vapor deposition (PECVD), physical vapor deposition (PVD), atomic layer deposition (ALD), decoupled plasma nitridation (DPN), rapid thermal processing (RTP), ashing, annealing, and etching, or any processing chamber utilized in electronic device fabrication. In one aspect, the processing sequence is adapted to form a high-K capacitor structure, where processing chambers 110 may be a DPN chamber, a CVD chamber capable of depositing poly-silicon, and/or a MCVD chamber capable of depositing titanium, tungsten, tantalum, platinum, or ruthenium.

In some aspects, the processing chamber 110 includes one or more lift pins. The lift pins are coupled to the substrate support. The substrate is transferred from the swapper to the lift pins. The lift pins then transfer the substrate to the substrate support. In some aspects, the substrate support is raised to sealingly engage with the process kit assembly to form an isolated processing region around the substrate where the substrate is subjected to a process, such as a PVD process. Once the process is complete, the substrate support is lowered and the substrate is disengaged from the substrate support by the lift pins. The substrate is then transferred from the lift pins and onto the swapper, such as by placing a support surface of the swapper underneath the substrate.

The factory interface 102 may be coupled to one or more front opening unified pods (FOUPs) 103. FOUPs 103 may each be a container having a stationary cassette therein for holding multiple substrates. FOUPs 103 may each have a front opening interface configured to be used with factory interface 102. Factory interface 102 may have a buffer chamber (not shown) and one or more robot assemblies 102a configured to transfer substrates via linear, rotational, and/or vertical movement between FOUPs 103 and the load locks 170. The factory interface 102 may include a set of FOUPs 103 and corresponding one or more robot assemblies 102a for each processing mainframe 101.

In some aspects, the processing chambers 110 are part of a monolithic structure, such as sharing a common housing. In some aspects, the swapper assembly 120 and the load locks 170 may each be part of a separate monolithic structure. Thus, in this case, the processing mainframe 101 may be formed by connecting a monolithic structure including the processing chambers 110 to one side of the monolithic structure of the swapper assembly 120 and then also connecting a monolithic structure including the load locks 170 to the other side of the monolithic structure including of the swapper assembly 120. Assembling the cluster tool 100 from monolithic structures, each including multiple components, such as processing chambers 110, load locks 170, or swapper assembly 120, decreases manufacturing and assembly costs and reduces the number of leak points. In some other aspects, the processing chambers 110, the swapper assembly 120 and the load locks 170 may each be part of a single monolithic structure that is used to support and provide a positional reference for the mounting and aligning of the various components to each other and to the monolithic structure.

The cluster tool 100 may also include a pumping system 181, a gas panel 182, a power supply 183, and an electronics module 184. The pumping system 181, gas panel 182, and power supply 183 are shown disposed underneath of the processing mainframe 101. The pumping system 181 is used to create and/or maintain a pressure within each processing chamber 110. For example, the pumping system 181 may be a vacuum pump or a plurality of vacuum pumps used to evacuate the processing chambers 110. The gas panel 182 may include one or more gases used to process a substrate in the processing chamber. The power supply 183 may be a power source, such as an AC power source or a DC power source, to operate electrical equipment of the cluster tool 100, such as operating equipment in the processing chamber 110, such as the source assembly. The power supply 183 may also include an optional RF power supply for the processing chambers 110, such as supplying RF power to a shower head or an electrostatic chuck of the processing chamber. The electronics module 184 may include electronics used to monitor and control the cluster tool 100. The electronics module 184 may be in communication with the controller 190.

In some aspects, the pumping system 181 is also used to create and maintain a pressure within the load locks 170, such as being used to evacuate each load lock 170. The pumping system 181 may also be used to create and maintain a pressure within the swapper assembly 120, such as being used to evacuate the swapper assembly 120. In some aspects, the cluster tool 100 includes a separate pumping system 181 for each of the processing chambers 110, the swapper assembly 120, and the load locks 170.

In some aspects, there is a pressure gradient in the processing mainframe 101. For example, the magnitude of the vacuum within the processing mainframe 101 may increase from the load lock 170 (highest pressure) to the interior of the processing chambers 110 (lowest pressure). The pumping system 181 may be used to maintain the pressure gradient.

In some aspects, the pumping system 181 may include one or more abatement modules to remove or break down chemicals or materials in the fore line to increase vacuum (e.g., exhaust) pump longevity.

In some aspects, each load lock 170 may include a heater assembly 178. The heater assembly 178 includes one or more heat sources that are positioned in the load lock 170 to be above the substrate. The heat sources may include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. In some aspects, the heater assembly 178 may be used to pre-heat the substrate. In some aspects, the heater assembly 178 may be used for a degas operation. The pumping system 181 connected to each load lock 170 may be used to remove emissions from the substrate during degassing.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the cluster tool 100, to facilitate control of the cluster tool 100. For example, in one or more aspects the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the cluster tool 100. The instructions in the memory are in the form of a program product such as a program that implements the methods of the present disclosure (e.g., middleware application, equipment software application, etc.). The program code may conform to any one of a number of different programming languages. In one or more aspects, the disclosure may be implemented as a program product stored on computer-readable storage media for use with a computer system. The program(s) of the program product define functions of the aspects (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are aspects of the present disclosure.

The various methods and operations disclosed herein may generally be implemented under the control of the CPU of the controller 190 by the CPU executing computer instruction code stored in the memory (or in memory of a particular processing chamber) as, e.g., a software routine. When the computer instruction code is executed by the CPU, the CPU controls the components of the cluster tool 100 to conduct operations in accordance with the various methods and operations described herein. In one or more aspects, the memory (a non-transitory computer readable medium) includes instructions stored therein that, when executed, cause the methods and operations described herein to be conducted. The operations described herein can be stored in the memory in the form of computer readable logic. While FIG. 1 provides a cluster tool as an example application in which certain aspects of the present disclosure may be implemented to facilitate understanding, certain aspects described herein may be used for any of various other suitable systems.

Certain aspects of the present disclosure are directed toward a matching network implemented in a radio frequency (RF) enclosure close to a chamber load, allowing for a reduction in current across a transmission line between a pre-matching and splitting circuit and the RF enclosure. The chamber load may be provided with a high frequency (HF) signal (e.g., an RF signal), which may have a frequency 13.5 MHz and a low frequency (LF) signal, which may have a frequency 350 KHz. The HF signal may be used to drive plasma generation inside the chamber and disassociation of reactive gases, while the LF signal provides ion energy to tune film stress for a substrate in the chamber. In some cases, the HF signal may be provided from a single HF signal generator (e.g., power supply 183 of FIGS. 1A and 1B) and split at a splitting node into multiple split paths for multiple chamber loads (e.g., chambers 110 of FIGS. 1A and 1B).

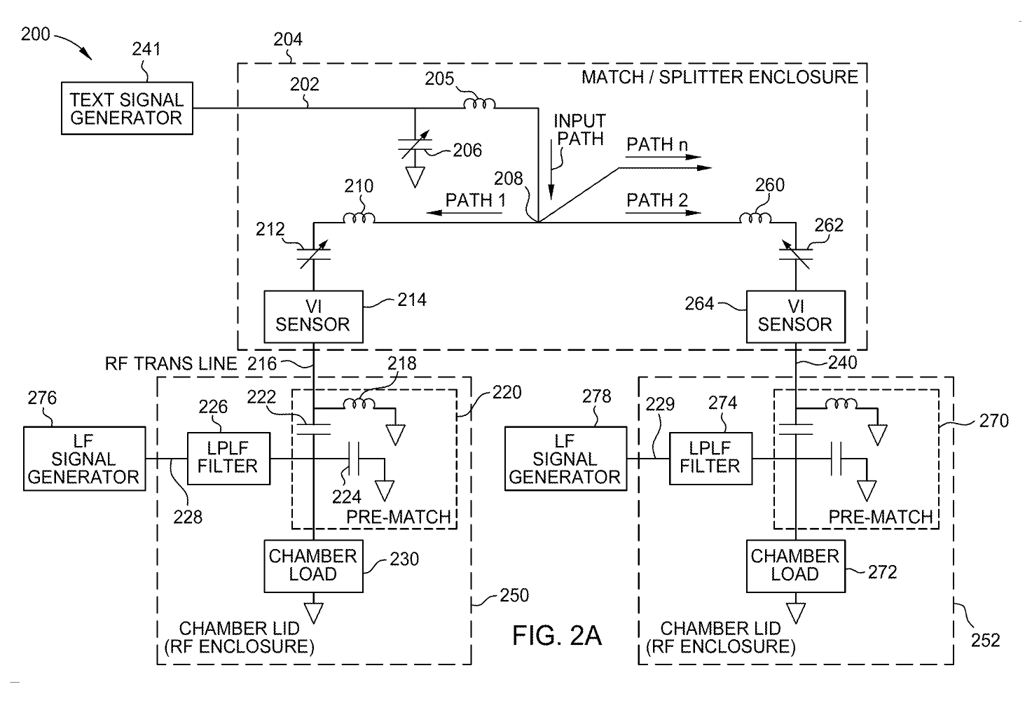

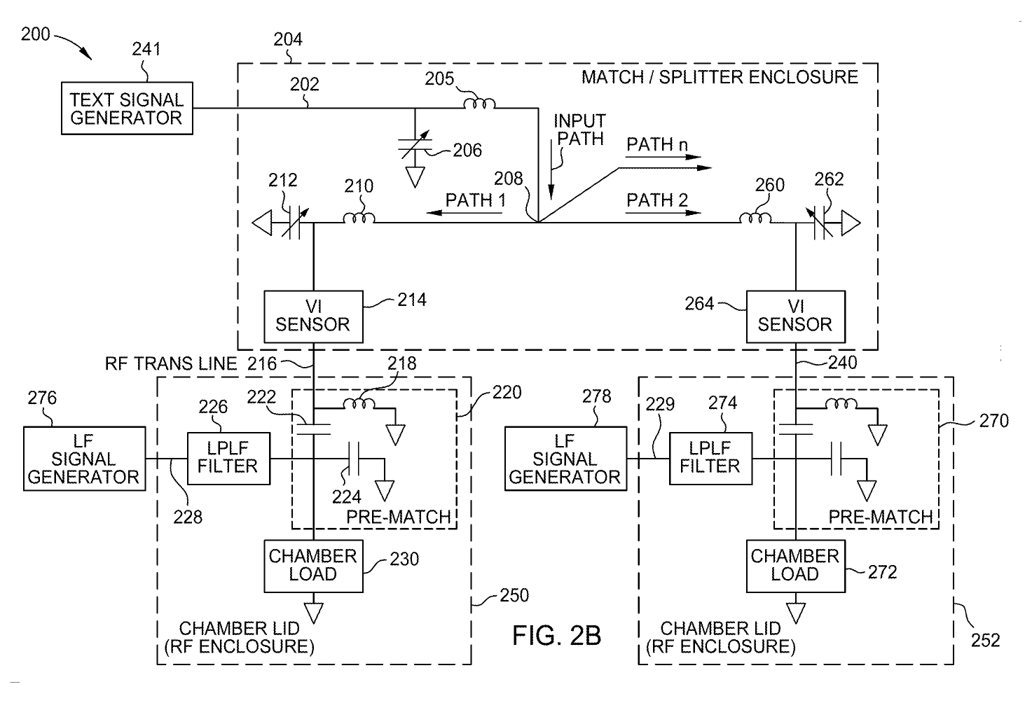

FIGS. 2A and 2B illustrate semiconductor processing circuitry 200 including splitting circuitry 204 coupled to multiple RF enclosures (also referred to herein as “chamber enclosures”) having matching networks, in accordance with certain aspects of the present disclosure. As shown in FIG. 2A, an HF signal generator 241 may provide an HF signal at an HF input 202 of the splitting circuitry 204. The splitting circuitry 204 may include a matching network implemented with an impedance including an inductive element 205 and a capacitive element 206. The capacitive element 206 may be coupled between the HF input 202 and a terminal of the inductive element 205 where a second terminal of the inductive element 205 is coupled to a splitting node 208. The splitting node 208 is used to split current from an input path coupled to the HF input 202 to multiple paths 1-n, n being a positive integer. For example, a current split from the input path may be provided to an RF enclosure via each of the paths 1-n. For example, path 1 may be coupled to RF enclosure 250 through an RF transmission line 216 and path 2 may be coupled to RF enclosure 252 through an RF transmission line 240. As shown in FIG. 2A, path 1 may include an impedance including an inductive element 210 and capacitive element 212 as part of the matching network of splitting circuitry 204. Similarly, path 2 may include an impedance including an inductive element 260 and capacitive element 262 as part of the matching network of the splitting circuitry 204. In some aspects, the capacitive element 212 may be coupled in shunt between the inductive element 210 and a reference potential node (e.g., electric ground) and the capacitive element 262 may be coupled in shunt between the inductive element 260 and a reference potential node (e.g., electric ground), as shown in FIG. 2B. The capacitive elements 206, 212, 262 may be variable capacitive elements, allowing for tuning of the impedance associated with the matching network. Each split path may include a voltage-current (VI) sensor for sensing the voltage and current of the signal provided to the respective RF enclosure. For example, the circuitry 204 may include a VI sensor 214 as part of path 1 and VI sensor 264 as part of path 2. The RF transmission lines 216, 240 may be coupled between VI sensors 214, 264 and RF enclosures 250, 252, respectively.

In some implementations, a matching network (e.g., pre-matching network, not shown in FIGS. 2A and 2B) may be implemented as part of each paths 1-n in the splitting circuitry 204. The current draw in each path is increased after the matching network. Thus, implementing the matching network as part of the split paths of the circuitry 204 results in increased current flow across the RF transmission line, resulting in increased power losses across the transmission line.

In certain aspects, the matching network may be implemented as part of the RF enclosures (e.g., instead of the splitting circuitry 204), reducing the current flow across the RF transmission line. By reducing the current flow across the RF transmission line, heat and power losses across the transmission line may be reduced. For example, as shown, the RF enclosure 250 may include a matching network 220 coupled between the chamber load 230 and the RF transmission line 216 and the RF enclosure 252 may include a matching network 270 coupled between the chamber load 272 and the transmission line 240. The matching network serves to increase the effective resistance of the RF enclosure (chamber load) as seen from the RF transmission line, reducing the current flow across the RF transmission line. In other words, if delivering a certain amount of power to the chamber load, if the effective resistance of the chamber load as seen from the transmission line is increased, the current flow across the transmission line would be decreased. Thus, the current flow from the matching network to the chamber load is greater than the current flow across the RF transmission line. Moreover, the current on the input path of the splitting circuitry 204 may be high as it may be n times the current of each of the split paths 1-n. The matching network reduces the current flow on each of the paths 1-n, reducing the current flow of the input path between the inductive element 205 and the splitting node 208.

An LF signal generator may provide an LF signal to each RF enclosure, as described herein. For example, LF signal generator 276 may provide an LF signal to an LF input 228 of RF enclosure 250 and LF signal generator 278 may provide an LF signal to an LF input 229 of RF enclosure 252. Each of the RF enclosures may include a low-pass filter (LPF) between the LF signal generator and the chamber load. For example, the RF enclosure 250 may include an LPF 226 coupled between the LF signal generator 276 and the chamber load 230 and the RF enclosure 252 may include a LPF 274 coupled between the LF signal generator 278 and the chamber load 272. As described, the HF signal may be used to drive plasma generation inside the chamber and disassociation of reactive gases, while the LF signal provides ion energy to tune film stress for a substrate in the chamber.

The matching networks of the RF enclosures (e.g., matching networks 220, 270) may be implemented using any suitable matching architecture. For example, the matching network 220 may be implemented with a capacitive element 222 coupled between the chamber load 230 and the RF transmission line 216. The matching network 220 may also include an inductive element 218 coupled between the reference potential node and a first terminal of the capacitive element 222 (or a second terminal of the matching network 220) coupled to the RF transmission line 216 and a capacitive element 224 coupled between a reference potential node (e.g., electric ground) and a second terminal of the capacitive element 222 (or a first terminal of the matching network 220) coupled to the chamber load 230. For instance, the first terminal of the matching network 220 may be coupled to a HF signal input port that is coupled to the RF transmission line 216. The second terminal of the matching network 220 may be coupled to an low-frequency signal input port coupled to the LF signal generator 276. The capacitive element 222 may serve to reduce the electrical coupling of the LF signal from the LF signal generator 276 to the HF signal generator 241 and reduce the electrical coupling of the LF signal from the LF signal generator 276 to other LF signal generators (e.g., LF signal generator 278).

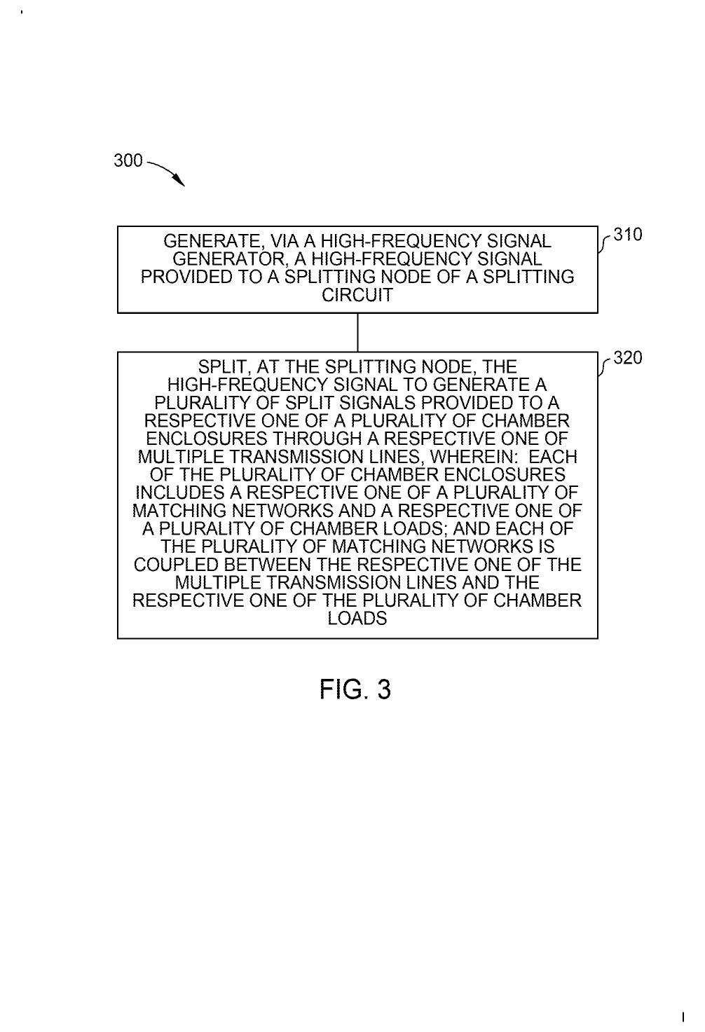

FIG. 3 is a flow diagram illustrating example operations 300 for semiconductor processing, in accordance with certain aspects of the present disclosure. The operations 300 may be performed, for example, by semiconductor processing circuitry, such a semiconductor processing circuitry 200 of FIG. 2A or FIG. 2B.

At block 302, the semiconductor processing circuitry may generate, via a high-frequency signal generator (e.g., HF signal generator 241), a high-frequency signal provided to a splitting node (e.g., splitting node 208) of a splitting circuit.

At block 304, the semiconductor processing circuitry may split, at the splitting node, the high-frequency signal to generate a plurality of split signals (e.g., on paths 1-n) provided to a respective one of the plurality of chamber enclosures (e.g., RF enclosures 250, 252) through a respective one of multiple transmission lines (e.g., transmission lines 216, 240). Each of the plurality of chamber enclosures may include a respective one of a plurality of matching networks (e.g., matching networks 220, 270) and a respective one of a plurality of chamber loads (e.g., chamber loads 230, 272). Each of the plurality of matching networks may be coupled between the respective one of the multiple transmission lines and the respective one of the plurality of chamber loads. The semiconductor processing circuitry may reduce, via each matching network of the plurality of matching networks, a current flow across the respective one of the multiple transmission lines as compared to a current flow from the matching network to the respective one of the chamber loads.

In some aspects, the semiconductor processing circuitry may also generate, via low-frequency signal generators (e.g., LF signal generators 276, 278), low-frequency signals provided to the respective one of the chamber loads. Each of the chamber enclosures may include a low-pass filter (e.g., LPFs 226, 274) coupled between a respective one of the low-frequency signal generators and the respective one of the chamber loads. The splitting circuit may include another matching network including at least an inductive element (e.g., inductive element 205) coupled between the high-frequency signal generator and the splitting node.

The semiconductor processing circuitry may also perform voltage or current sensing via sensors (e.g., VI sensors 214, 264) coupled between the splitting node and the respective one of the multiple transmission lines. Each of the plurality of matching networks may include a capacitive element (e.g., capacitive element 222) coupled between the respective one of the chamber loads and the respective one of the transmission lines. Each of the plurality of matching networks may include a first impedance (e.g., inductive element 218) coupled between a terminal of the capacitive element and a reference potential node (e.g., electric ground). Each of the plurality of matching networks may also include a second impedance (e.g., capacitive element 224) coupled between another terminal of the capacitive element and the reference potential node.

While the foregoing is directed to aspects of the present disclosure, other and further aspects of the disclosure may be devised without departing from the basic scope thereof, and the scope thereof is determined by the claims that follow.

What is claimed is:

1. An apparatus for semiconductor processing, including:
a plurality of chamber enclosures, each including a respective one of a plurality of matching networks and a respective one of a plurality of chamber loads; and
a splitting circuit having an input path coupled to a splitting node, wherein:
multiple split paths are coupled between the splitting node and a respective one of the plurality of chamber enclosures through a respective one of multiple transmission lines; and
each of the plurality of matching networks is coupled between the respective one of the multiple transmission lines and the respective one of the plurality of chamber loads.

2. The apparatus of claim 1, further comprising:
a high-frequency signal generator coupled to the input path; and
low-frequency signal generators having outputs coupled to the respective one of the chamber loads.

3. The apparatus of claim 2, wherein each of the chamber enclosures includes a low-pass filter coupled between a respective one of the low-frequency signal generators and the respective one of the chamber loads.

4. The apparatus of claim 2, wherein the splitting circuit comprises another matching network including at least an inductive element coupled between the high-frequency signal generator and the splitting node.

5. The apparatus of claim 1, wherein the splitting circuit further comprises sensors coupled between the splitting node and the respective one of the multiple transmission lines.

6. The apparatus of claim 1, wherein each of the plurality of matching networks comprises a capacitive element coupled between the respective one of the chamber loads and the respective one of the transmission lines.

7. The apparatus of claim 6, wherein each of the plurality of matching networks comprises:
a first impedance coupled between a terminal of the capacitive element and a reference potential node; and
a second impedance coupled between another terminal of the capacitive element and the reference potential node.

8. The apparatus of claim 7, wherein the first impedance comprises an inductive element, and wherein the second impedance comprises another capacitive element.

9. The apparatus of claim 8, wherein each matching network of the plurality of matching networks is configured to reduce a current flow across the respective one of the multiple transmission lines as compared to a current flow from the matching network to the respective one of the chamber loads.

10. The apparatus of claim 1, wherein each of the multiple split paths comprises an inductive element and a capacitive element coupled between the splitting node and the respective one of the multiple transmission lines.

11. A method for semiconductor processing, including:
generating, via a high-frequency signal generator, a high-frequency signal provided to a splitting node of a splitting circuit; and
splitting, at the splitting node, the high-frequency signal to generate a plurality of split signals provided to a respective one of a plurality of chamber enclosures through a respective one of multiple transmission lines, wherein:
each of the plurality of chamber enclosures includes a respective one of a plurality of matching networks and a respective one of a plurality of chamber loads; and
each of the plurality of matching networks is coupled between the respective one of the multiple transmission lines and the respective one of the plurality of chamber loads.

12. The method of claim 11, further comprising generating, via low-frequency signal generators, low-frequency signals provided to the respective one of the chamber loads.

13. The method of claim 12, wherein each of the chamber enclosures includes a low-pass filter coupled between a respective one of the low-frequency signal generators and the respective one of the chamber loads.

14. The method of claim 12, wherein the splitting circuit comprises another matching network including at least an inductive element coupled between the high-frequency signal generator and the splitting node.

15. The method of claim 11, further comprising performing voltage or current sensing via sensors coupled between the splitting node and the respective one of the multiple transmission lines.

16. The method of claim 11, wherein each of the plurality of matching networks comprises a capacitive element coupled between the respective one of the chamber loads and the respective one of the transmission lines.

17. The method of claim 16, wherein each of the plurality of matching networks comprises:
a first impedance coupled between a terminal of the capacitive element and a reference potential node; and
a second impedance coupled between another terminal of the capacitive element and the reference potential node.

18. The method of claim 17, wherein the first impedance comprises an inductive element, and wherein the second impedance comprises another capacitive element.

19. The method of claim 18, further comprising reducing, via each matching network of the plurality of matching networks, a current flow across the respective one of the multiple transmission lines as compared to a current flow from the matching network to the respective one of the chamber loads.

20. A chamber enclosure, including:
a chamber load;
a high-frequency signal input port;
a matching network having a first terminal coupled to the high-frequency signal input port and a second terminal coupled the chamber load; and
a low-frequency signal input port coupled to the second terminal of the matching network.

21. A splitting circuit, comprising:
an input path coupled to a splitting node; and
multiple split paths coupled between the splitting node and a respective one of a plurality of chamber enclosures through a respective one of multiple transmission lines, wherein the input path includes a first impedance and each of the multiple split paths include a second impedance, the first impedance and the second impedance forming a matching network, wherein the second impedance is coupled the respective one of the transmission lines without another matching network.
